(19) United States
(12) Patent Application Publication
(10) Pub. No.: US 2025/0224684 A1
(43) Pub. Date: Jul. 10, 2025

(54) ANALYTIC METHOD AND DEVICE FOR QUANTITATIVELY CALCULATING LINE EDGE ROUGHNESS IN PLASMA ULTRA-DIFFRACTION PHOTOETCHING PROCESS

(71) Applicant: INSTITUTE OF MICROELECTRONICS, CHINESE ACADEMY OF SCIENCES, Beijing (CN)

(72) Inventors: Dandan Han, Beijing (CN); Yayi Wei, Beijing (CN)

(21) Appl. No.: 18/681,014

(22) PCT Filed: Dec. 29, 2021
(86) PCT No.: PCT/CN2021/142263

§ 371 Date: Feb. 2, 2024

(30) Foreign Application Priority Data
Oct. 26, 2021 (CN) 202111248125.2

(51) Int. Cl. G03F 7/00; G01Q 60/24

(52) U.S. Cl. CPC G03F 7/70625; G01Q 60/24; G03F 7/70375; G03F 7/70655; G03F 7/706837; G03F 7/706839

(57) ABSTRACT

An analytical method and an analytical apparatus for quantitatively calculating line edge roughness of plasmon super diffraction photolithography. The method includes: determining a theoretical point spread function of a light source based on field intensity distribution of the light source at an exit plane of a focusing element of the plasmon super diffraction photolithography; determining multiple transverse widths of spots in a spot-mapping pattern based on the spot-mapping pattern; determining actual point spread functions corresponding to the multiple transverse widths, based on the theoretical point spread function and the multiple transverse widths; and establishing an analytical equation of line edge roughness of the plasmon super diffraction photolithography based on the variation due to line edge roughness, an exposure dose of each line pattern, the near-field photoresist contrast, and the logarithmic slope of each line pattern. Applicability of surface plasma super diffraction photolithography technology is greatly improved.

The present disclosure claims priority to Chinese Patent Application No. CN202111248125.2 titled “ANALYTICAL METHOD AND APPARATUS FOR QUANTITATIVELY CALCULATING LINE EDGE ROUGHNESS OF PLASMON SUPER DIFFRACTION PHOTOLITHOGRAPHY”, filed on Dec. 26, 2021 with the China National Intellectual Property Administration, which is incorporated herein by reference in its entirety.

### FIELD

The present disclosure relates to the field of semiconductor manufacturing, and in particular to an analytical method and an apparatus for quantitatively calculating line edge roughness of plasmon super diffraction photolithography.

### BACKGROUND

Surface plasmon (SP) super diffraction photolithography is a nano-level photolithography technique that can circumvent the diffraction limit. When exposed to an ultraviolet light source, a bowtie nano-aperture (BNA) structure is utilized to generate a mode of surface plasmon polaritons (SPPs) and a diffraction field of quasi-spherical waves (QSWs), such that an exposure pattern is transferred onto a photoresist (PR), implementing super-resolution imaging. The SP super diffraction photolithography is a novel nano-processing technique that has high resolution and a low cost. It has been verified that the SP super diffraction photolithography has a resolution approximating 10 nm. The SP super diffraction photolithograph has good controllability and good scalability under a nano-level critical dimension, and hence various surface micro/nano structures, ranging from one-dimensional ones to three dimensional ones, have been successfully manufactured. In addition, a method has been proposed based on a characteristic of near-field imaging in the SP super diffraction photolithography for compensating a proximity effect caused by a near-field evanescent wave, which improves quality of the exposure pattern greatly. A technology node of nano-level photolithography has been reduced to be less than 20 nm due to an increasing requirement on a dimension and quality of nanostructured devices in integrated circuits. Under such a small critical dimension (CD), line edge roughness (LER) of the exposure pattern has become a significant issue in the SP super diffraction photolithography.

The LER refers to edge roughness of the exposure pattern on a surface of a photoresist. Generally, the LER is not reduced along with a decrease of the critical dimension of the exposure pattern. When manufacturing a micro nanostructured device, a large LER not only deteriorates actual performances of the manufactured device, but also has a strong limit on resolution and fidelity of photolithography when critical dimension is decreased. Therefore, in order to improve quality and performances of the micro nanostructured device in practice, it is required to evaluate the LER of the exposure pattern in photolithography and seek a solution for reducing the LER.

At present, the LER of the exposure pattern is usually determined through Monte Carlo simulation. As a widely used method concerning a mathematical random model, the Monte Carlo simulation is very useful for studying a mechanism of how the LER is produced in nano-level photolithography and performing approximate calculation on the LER in nano-level photolithography. A reason lies in that the Monte Carlo simulation is capable to implement approximate calculation on the LER of the exposure pattern having an arbitrary critical dimension, and establish a strict model for analyzing a random mechanism possible to cause the LER in each process (i.e. exposure, development, measurement, and etching) in the nano-level photolithography.

During operation, the Monte Carlo simulation requires a lot of computation in each random step, so as to provide a correct statistical result. Thus, the Monte Carlo simulation is deficient in a long operation period and cannot be applied to a large exposure pattern. Moreover, the Monte Carlo simulation is based on a series of parameter configurations and a large amount of statistical data, and hence a physical mechanism of producing the LER may be neglected. A superficial research on producing mechanisms and theoretical calculation on the LER results in inaccurate and unreliable evaluation on the LER in the SP super diffraction photolithography.

### SUMMARY

An analytical method and an apparatus for quantitatively calculating line edge roughness of plasmon super diffraction photolithography are provided according to embodiments of the present disclosure, in order to address an issue that line edge roughness of surface plasmon super diffraction photolithography cannot be accurately and reliably evaluated in conventional technology.

In a first aspect, an analytical method for quantitatively calculating line edge roughness of plasmon super diffraction photolithography is provided. The method includes: determining a theoretical point spread function of a light source based on field intensity distribution of the light source at an exit plane of a focusing element of the plasmon super diffraction photolithography; determining multiple transverse widths of spots in a spot-mapping pattern imaged from the light source onto a surface of a photoresist of the plasmon super diffraction photolithography, through performing atomic force microscopy on the spot-mapping pattern; determining actual point spread functions corresponding to the multiple transverse widths, based on the theoretical point spread function and the multiple transverse widths; determining actual line spread functions of line patterns corresponding to different critical dimensions based on multiple attenuation parameters and the actual point spread functions, which correspond to the multiple transverse widths, determining a transverse attenuation characteristic of a near-field evanescent wave of the light source based on the actual line spread functions and the actual point spread functions; determining a near-field photoresist contrast and a logarithmic slope of the spot-mapping pattern according to the transverse attenuation characteristic; determining a variation due to line edge roughness at two boundaries of each line pattern corresponding to one of the actual line spread functions, based on position coordinates at the two boundaries of said line pattern; determining the near-field photoresist contrast of each line pattern; and establishing an analytical equation of line edge roughness of the plasmon super diffraction photolithography based on the variation due to line edge roughness, an exposure dose of each line pattern, the near-field photoresist contrast, and the logarithmic slope of each line pattern.

According to the above technical solution, the analytical method for quantitatively calculating line edge roughness of plasmon super diffraction photolithography is provided according to embodiments of the present disclosure. The theoretical point spread function of the light source is determined based on the field intensity distribution of the light source at the exit plane of the focusing element for the plasmon super diffraction photolithography. The multiple transverse widths of spots in the spot-mapping pattern imaged from the light source onto the surface of the photoresist of the plasmon super diffraction photolithography are determined through performing atomic force microscopy on the spot-mapping pattern. The actual point spread functions corresponding to the multiple transverse widths are determined based on the theoretical point spread function and the multiple transverse widths. The actual line spread functions of line patterns corresponding to different critical dimensions are determined based on the multiple attenuation parameters and the actual point spread functions, which correspond to the multiple transverse widths. The transverse attenuation characteristic of the near-field evanescent wave of the light source is determined based on the actual line spread functions and the actual point spread functions. The near-field photoresist contrast and the logarithmic slope of the spot-mapping pattern are determined according to the transverse attenuation characteristic. The variation due to line edge roughness at the two boundaries of each line pattern corresponding to one of the actual line spread functions is determined based on the position coordinates at the two boundaries of said line pattern. The near-field photoresist contrast of each line pattern is determined. The analytical equation of line edge roughness of the plasmon super diffraction photolithography is determined based on the variation due to line edge roughness, the exposure dose of each line pattern, the near-field photoresist contrast, and the logarithmic slope of said line pattern. The method is capable to analyze a nature of a producing mechanism of line edge roughness in the surface plasmon super diffraction photolithography, evaluate line edge roughness under different critical dimensions accurately, and provide a theoretical guidance for reducing the line edge roughness. For example, the logarithmic slope of the spot-mapping pattern may be increased by decreasing a gap of a bowtie nano-aperture, in order to reduce the line edge roughness and improve quality of the exposure pattern of surface plasmon super diffraction photolithography. In comparison with Monte Carlo simulation, the analytical method for quantitatively calculating line edge roughness of plasmon super diffraction photolithography according to embodiments the present disclosure is more suitable for a large exposure patter, and thereby applicability of the surface plasmon super diffraction photolithography is greatly improved.

In an embodiment, determining the near-field photoresist contrast of each line pattern includes: determining a photoresist contrast induced by near-field attenuation; and determining the near-field photoresist contrast based on a far-field photoresist contrast and the photoresist contrast induced by the near-field attenuation.

In an embodiment, determining the photoresist contrast induced by the near-field attenuation includes: acquiring the spot-mapping pattern imaged from the light source onto the surface of the photoresist in an experiment of the plasmon super diffraction photolithography; determining multiple transverse widths of spots in the spot-mapping pattern through atomic force microscopy; determining a far-field experimental photoresist contrast and a near-field experimental photoresist contrast, based on the multiple transverse widths of spots in the spot-mapping pattern and exposure doses corresponding to the multiple transverse widths of spots in the spot-mapping pattern; and determining the photoresist contrast induced by the near-field attenuation based on the far-field experimental photoresist contrast and the near-field experimental photoresist contrast.

In an embodiment, the near-field photoresist contrast is determined based on:

$${γ}_{near}^{- 1} = {γ}_{far}^{- 1} + {γ}_{decay}^{- 1} ,$$

where γₙₑₐᵣ represents the near-field photoresist contrast, γ_{far} represents the far-field photoresist contrast, and γ_{decay} represents the photoresist contrast induced by the near-field attenuation.

In an embodiment, establishing the analytical equation of line edge roughness of the plasmon super diffraction photolithography based on the variation due to line edge roughness, the exposure dose of each line pattern, the near-field photoresist contrast, and the logarithmic slope of each line pattern includes: establishing an equation for the variation due to line edge roughness based on the variation due to line edge roughness; and establishing the analytical equation of line edge roughness of the plasmon super diffraction photolithography based on the equation for the variation due to line edge roughness, the exposure dose of each line pattern, the near-field photoresist contrast, and the logarithmic slope of each line pattern.

In an embodiment, the field intensity distribution is determined based on surface plasmon polaritons and an evanescent-wave mode of a quasi-spherical wave. When a critical dimension of an exposure pattern is equal to 1/10 of a wavelength of a light radiated by the light source, a field intensity of the surface plasmon polaritons decreases with a factor of 1/ρ², and an analytical equation for the theoretical point spread function is:

$${D}_{psf} ( ρ , φ ) = ( \frac{{A}_{qsw}^{2}}{{ρ}^{2}} + \frac{{A}_{spp}^{2}}{{ρ}^{2}} + \frac{{A}_{qsw} {A}_{spp}}{ρ \sqrt{ρ}} cos ( ϕ - δ ) ) cos {φ}^{2} ,$$

where D_{psf}(ρ,φ) represents the theoretical point spread function, ρ represents a transverse length of a spot, spp represents the surface plasmon polaritons, qsw represents the quasi-spherical wave, A_{SPP} represents amplitude of the surface plasmon polaritons, A_{QSW} represents amplitude of the evanescent-wave mode of the quasi-spherical wave, and ϕ−δ represents a phase delay between the surface plasmon polaritons and the quasi-spherical wave.

In an embodiment, determining the near-field photoresist contrast and the logarithmic slope of the spot-mapping pattern according to the transverse attenuation characteristic includes: determining a correspondence between the near-field photoresist contrast and the logarithmic slope according to the transverse attenuation characteristic; and determining the logarithmic slope according to the near-field photoresist contrast and the correspondence.

In an embodiment, determining the actual line spread functions of the line patterns corresponding to the different critical dimensions based on the multiple attenuation parameters and the actual point spread functions, which correspond to the multiple transverse widths, includes: determining the multiple attenuation parameters at edges of the points; and determining the actual line spread functions through convolution between the actual point spread functions and the line pattern, where the convolution is performed by utilizing the multiple attenuation parameters based on a linear convolution relationship between the points in the spot-mapping pattern and the line patterns. Determining the multiple attenuation parameters at edges of the points includes: acquiring an exposure dose at an edge of one of the points; and fitting the exposure dose to determine one of the multiple attenuation parameters.

In an embodiment, after establishing the analytical equation of the line edge roughness of the plasmon super diffraction photolithography based on the variation due to line edge roughness, the exposure dose of each line pattern, the near-field photoresist contrast, and the logarithmic slope of each line pattern, the method further includes: determining theoretical line edge roughness of the plasmon super diffraction photolithography based on the analytical equation; acquiring the line patterns corresponding to the different critical dimensions on the surface of the photoresist in the plasmon super diffraction photolithography; processing an image of the line patterns to determine actual line edge roughness corresponding to the line patterns; and determining accuracy of the analytical equation based on the theoretical line edge roughness and the actual line edge roughness.

In an embodiment, the analytical equation of the line edge roughness is:

$$3 {σ}_{LER} ≅ \frac{3}{\sqrt{{D}_{nor}}} {e}^{\frac{1}{{r}_{near}}} ( \frac{1}{ILS} ) ,$$

where σ_{LER} represents theoretical line edge roughness, Dₙₒᵣ represents the exposure dose that is normalized, rₙₑₐᵣ represents the near-field photoresist contrast, and ILS represents the logarithmic slope of the pattern.

In a second aspect, an analytical apparatus for quantitatively calculating line edge roughness of plasmon super diffraction photolithography is further provided. The device includes: a first determining module, configure to determine a theoretical point spread function of a light source based on field intensity distribution of the light source at an exit plane of a focusing element of the plasmon super diffraction photolithography; a second determining module, configured to determine multiple transverse widths of spots in a spot-mapping pattern imaged from the light source onto a surface of a photoresist of the plasmon super diffraction photolithography, through performing atomic force microscopy on the spot-mapping pattern; a third determining module, configured to determine actual point spread functions corresponding to the multiple transverse widths, based on the theoretical point spread function and the multiple transverse widths; a fourth determining module, configured to determine actual line spread functions of line patterns corresponding to different critical dimensions based on multiple attenuation parameters and the actual point spread functions, which correspond to the multiple transverse widths; a fifth determining module, configured to determine a transverse attenuation characteristic of a near-field evanescent wave of the light source based on the actual line spread functions and the actual point spread functions; a sixth determining module, configured to determine a near-field photoresist contrast and a logarithmic slope of the spot-mapping pattern according to the transverse attenuation characteristic; a seventh determining module, configured to determine a variation due to line edge roughness at two boundaries of each line pattern corresponding to one of the actual line spread functions, based on position coordinates at the two boundaries of said line pattern; an eighth determining module, configured to determine the near-field photoresist contrast of each line pattern; and a ninth determining module, configured to establish an analytical equation of line edge roughness of the plasmon super diffraction photolithography based on the variation due to line edge roughness, an exposure dose of each line pattern, the near-field photoresist contrast, and the logarithmic slope of each line pattern.

In an embodiment, the eighth determining module includes: a first determining submodule, configured to determine a photoresist contrast induced by near-field attenuation; and a second determining submodule, configured to determine the near-field photoresist contrast based on a far-field photoresist contrast and the photoresist contrast induced by the near-field attenuation.

In an embodiment, the first determining submodule includes: a first acquiring unit, configured to acquire the spot-mapping pattern imaged from the light source onto the surface of the photoresist in an experiment of the plasmon super diffraction photolithography; a first determining unit, configured to determine multiple transverse widths of spots in the spot-mapping pattern through atomic force microscopy; a second determining unit, configured to determine an far-field experimental photoresist contrast and a near-field experimental photoresist contrast, based on the multiple transverse widths and exposure doses corresponding to the multiple transverse widths; and a third determining unit, configured to determine the photoresist contrast induced by the near-field attenuation based on the far-field experimental photoresist contrast and the near-field experimental photoresist contrast.

In an embodiment, the near-field photoresist contrast is determined based on:

$${γ}_{near}^{- 1} = {γ}_{far}^{- 1} + {γ}_{decay}^{- 1} ,$$

where γₙₑₐᵣ represents the near-field photoresist contrast, γ_{far} represents the far-field photoresist contrast, and γ_{decay} represents the photoresist contrast induced by the near-field attenuation.

In an embodiment, the ninth determining module includes: a third determining submodule, configured to establish an equation for the variation due to line edge roughness based on the variation due to line edge roughness, and a fourth determining submodule, configured to establish the analytical equation of line edge roughness of the plasmon super diffraction photolithography based on the equation for the variation due to line edge roughness, the exposure dose of each line pattern, the near-field photoresist contrast, and the logarithmic slope of each line pattern.

In an embodiment, the field intensity distribution is determined based on surface plasmon polaritons and an evanescent-wave mode of a quasi-spherical wave. When a critical dimension of an exposure pattern is equal to 1/10 of a wavelength of a light radiated by the light source, a field intensity of the surface plasmon polaritons decreases with a factor of 1/ρ², and an analytical equation for the theoretical point spread function is:

$${D}_{psf} ( ρ , φ ) = ( \frac{{A}_{qsw}^{2}}{{ρ}^{2}} + \frac{{A}_{spp}^{2}}{{ρ}^{2}} + \frac{{A}_{qsw} {A}_{spp}}{ρ \sqrt{ρ}} cos ( ϕ - δ ) ) cos {φ}^{2} ,$$

where D_{psf}(ρ,φ) represents the theoretical point spread function, ρ represents a transverse length of a spot, spp represents the surface plasmon polaritons, qsw represents the quasi-spherical wave, A_{SPP} represents amplitude of the surface plasmon polaritons, A_{QSW} represents amplitude of the evanescent-wave mode of the quasi-spherical wave, and ϕ−δ represents a phase delay between the surface plasmon polaritons and the quasi-spherical wave.

In an embodiment, the sixth determining module includes a fifth determining submodule, configured to determine a correspondence between the near-field photoresist contrast and the logarithmic slope according to the transverse attenuation characteristic; and a sixth determining submodule, configured to determine the logarithmic slope according to the near-field photoresist contrast and the correspondence.

In an embodiment, the fourth determining module includes: a seventh determining submodule, configured to determine the multiple attenuation parameters at edges of the points; and an eighth determining submodule, configured to determine the actual line spread functions through convolution between the actual point spread functions and the line pattern, where the convolution is performed by utilizing the multiple attenuation parameters based on a linear convolution relationship between the points in the spot-mapping pattern and the line patterns. The seventh determining submodule includes: a second acquiring unit, configured to acquire an exposure dose at an edge of one of the points; and a fourth determining unit, configured to fit the exposure dose to determine one of the multiple attenuation parameters.

In an embodiment, the method further includes: a tenth determining module, configured to determine theoretical line edge roughness of the plasmon super diffraction photolithography based on the analytical equation; an acquiring module, configured acquire the line patterns corresponding to the different critical dimensions on the surface of the photoresist in the plasmon super diffraction photolithography; an eleventh determining module, configured to process an image of the line patterns to determine actual line edge roughness corresponding to the line patterns; and a twelfth determining module, configured to determine accuracy of the analytical equation based on the theoretical line edge roughness and the actual line edge roughness.

In an embodiment, the analytical equation of the line edge roughness is:

$$3 {σ}_{LER} ≅ \frac{3}{\sqrt{{D}_{nor}}} {e}^{\frac{1}{{r}_{near}}} ( \frac{1}{ILS} ) ,$$

where σ_{LER} represents theoretical line edge roughness, Dₙₒᵣ represents the exposure dose that is normalized, rₙₑₐᵣ represents the near-field photoresist contrast, and ILS represents the logarithmic slope of the pattern.

Beneficial effects of the analytical apparatus according to the second aspect are same as those of the analytical method that is described in the first aspect, or any embodiment in the first aspect, and hence are not repeated herein.

### BRIEF DESCRIPTION OF THE DINITIALINGS

The drawings described herein are intended for providing further understanding on the present disclosure and constitute a part of the present disclosure. Exemplary embodiments of the present disclosure and the description thereof are used for explaining the present disclosure rather than limiting the present disclosure.

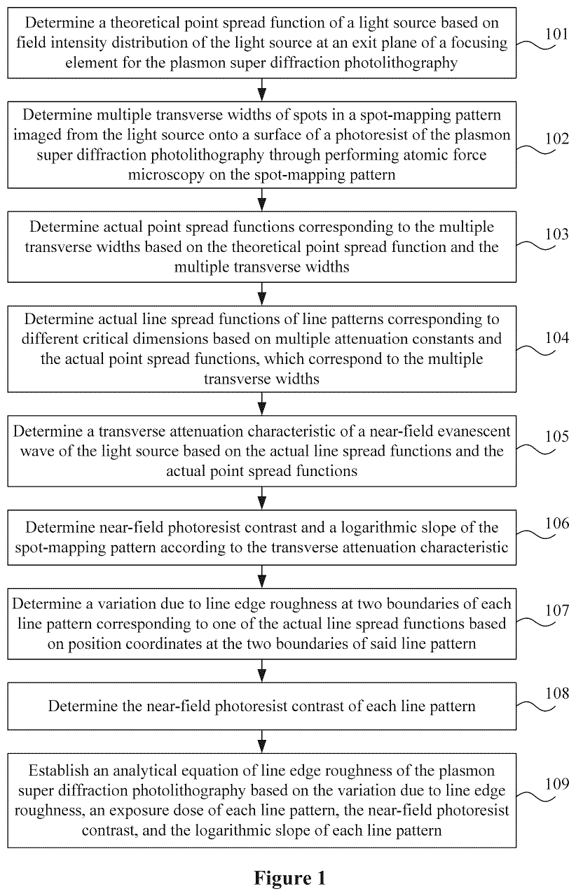

FIG. 1 is a flow chart of an analytical method for quantitatively calculating line edge roughness of plasmon super diffraction photolithography according to an embodiment of the present disclosure.

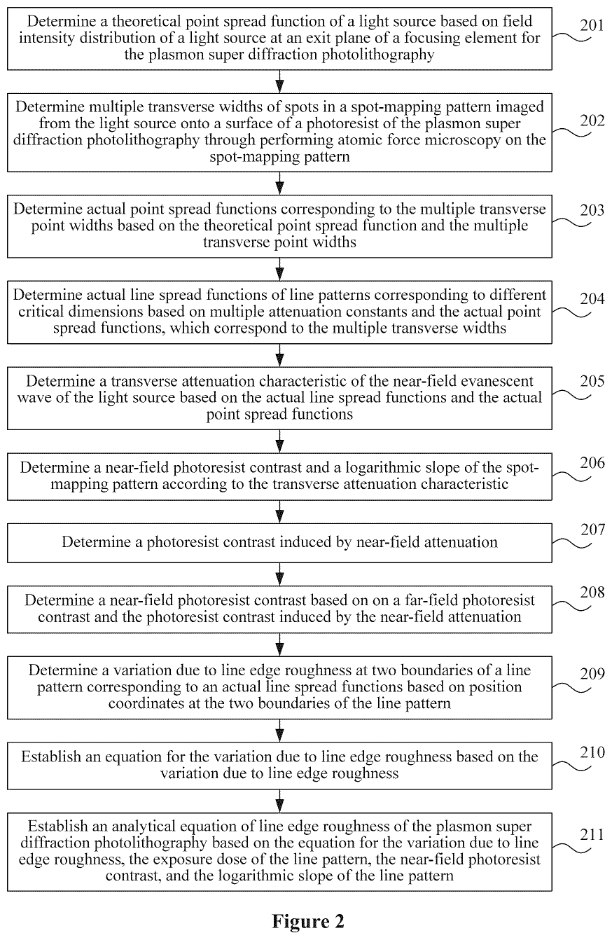

FIG. 2 is a flow chart of an analytical method for quantitatively calculating line edge roughness of plasmon super diffraction photolithography according to another embodiment of the present disclosure.

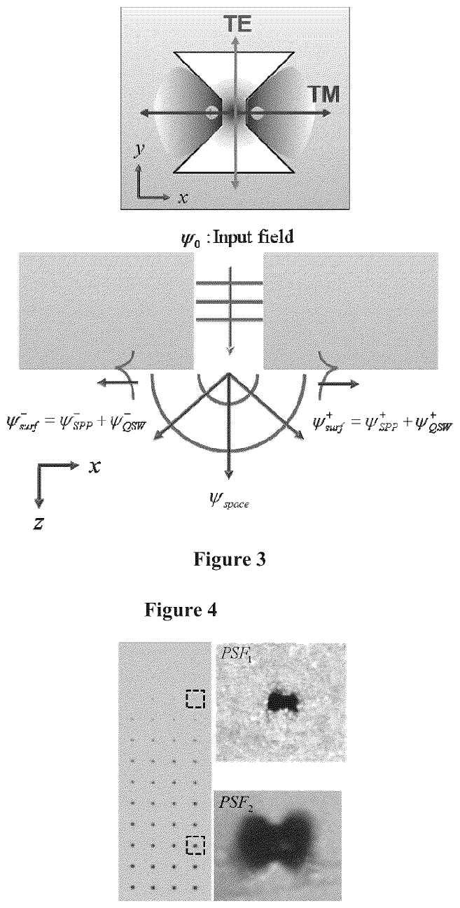

FIG. 3 is a diagram showing field strength distribution at an exit plane of a bowtie nano-aperture for surface plasmon super diffraction photolithography according to an embodiment of the present disclosure.

FIG. 4 is a schematic diagram showing a spot-mapping pattern and point spread functions corresponding to different critical dimensions according to an embodiment of the present disclosure.

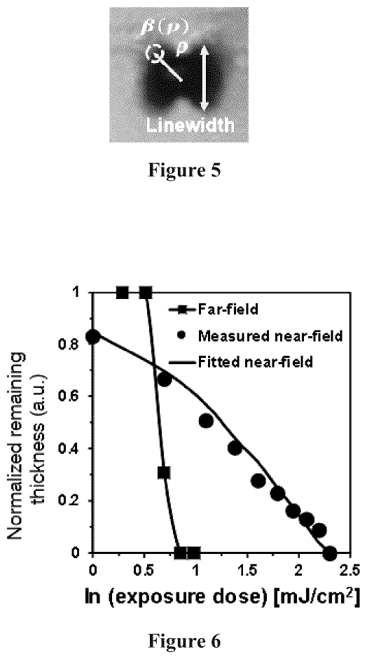

FIG. 5 is a schematic diagram showing a pattern of a point measured through atomic force microscopy and an attenuation parameter β(ρ) at a transverse distance ρ according to an embodiment of the present disclosure.

FIG. 6 is a schematic diagram showing a far-field photoresist contrast curve in a conventional photolithography system and a near-field photoresist contrast curve in a surface plasmon super diffraction photolithography system according to an embodiment of the present disclosure.

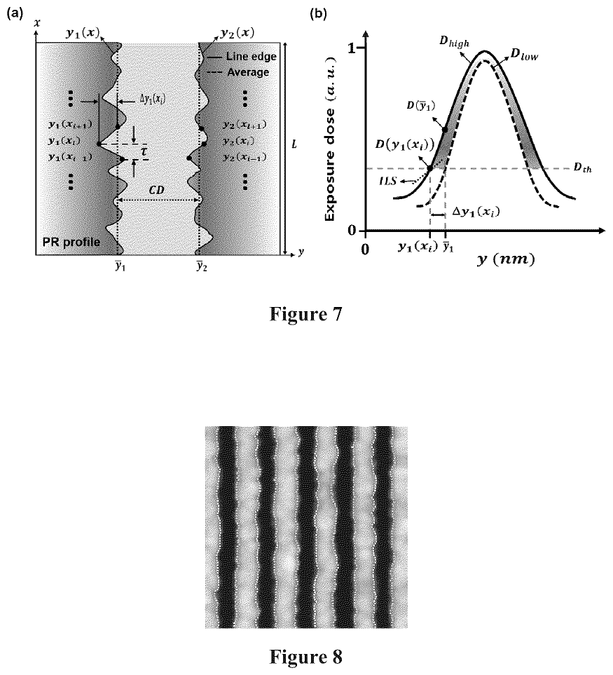

FIG. 7 shows a diagram of characterizing line edge roughness in nano-level photolithography and curves of exposure dose distribution in photoresist corresponding to different critical dimensions according to an embodiment of the present disclosure.

FIG. 8 is a schematic diagram showing a line pattern and edge extraction performed on the line pattern according to an embodiment of the present disclosure.

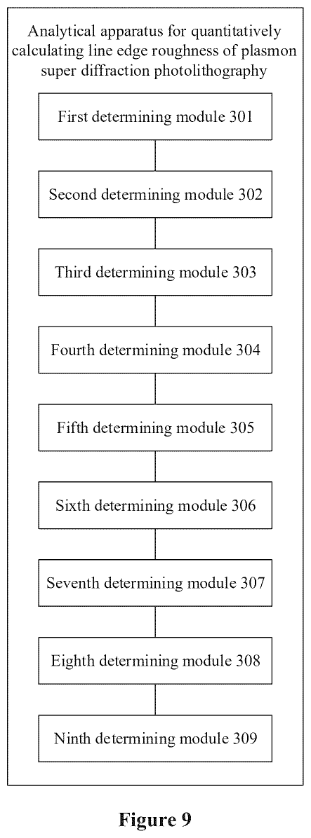

FIG. 9 is a schematic structural diagram of an analytical apparatus for quantitatively calculating line edge roughness of plasmon super diffraction photolithography according to an embodiment of the present disclosure.

### DETAILED DESCRIPTION OF EMBODIMENTS

In order to clearly describe technical solutions, terms such as “first” and “second” are used to distinguish same or similar items having substantially identical functions in embodiments of the present disclosure. For example, a “first” threshold and a “second” threshold are merely configured to distinguish different thresholds, rather than limiting an order of two thresholds. Those skilled in the art may understand that the terms “first” and “second” do not limit a quantity and an operation order, and the terms “first” and “second” are not necessarily limited to indicate different entities.

Herein terms “exemplary” or “for example” are used to indicate examples, instances, or illustrations. Any embodiment or solution described as “exemplary” or “for example” herein should not be interpreted as more preferred or more advantageous than other embodiments or solutions. Specifically, the terms “exemplary” or “for example” aims to present a relevant concept in a specific way.

Herein the term “at least one” refers to one or more, and the term “multiple” refers to two or more. The term “and/or” describes a relationship between associated objects, and indicates that there may be three candidate relationships. For example, “A and/or B” may indicate a case that there is only A, a case that there are both A and B, and a case that there is only B, and both A and B may have a quantity of one or more in such cases. Generally, a symbol “/” indicates that a former object and a latter object are associated by an alternative (“or”) relationship. The term “at least one of following” or similar expressions refer to any combination of following items, including any combination of a single item or multiple items. For example, “at least one of a, b, or c” may indicate a case that there is only a, a case that there is only b, a case that there is only c, a case that there are both a and b, a case that there are both b and c, a case that there are both a and c, or a case that there are both a, b, and c. Each of a, b, and c may have a quantity of one or more in such cases.

FIG. 1 is a flow chart of an analytical method for quantitatively calculating line edge roughness of plasmon super diffraction photolithography according to an embodiment of the present disclosure. As shown in FIG. 1, the analytical method includes following steps 101 to 109.

In step 101, a theoretical point spread function of a light source is determined based on field intensity distribution of the light source at an exit plane of a focusing element for the plasmon super diffraction photolithography.

In an embodiment, the field intensity distribution data is determined based on surface plasmon polaritons and an evanescent-wave mode of a quasi-spherical wave. When a critical dimension of an exposure pattern is equal to 1/10 of a wavelength of a light radiated by the light source, a field intensity of the surface plasmon polaritons decreases with a factor of 1/ρ², and an analytical equation for the theoretical point spread function is as follows.

$${D}_{psf} ( ρ , φ ) = ( \frac{{A}_{qsw}^{2}}{{ρ}^{2}} + \frac{{A}_{spp}^{2}}{ρ} + \frac{{A}_{qsw} {A}_{spp}}{ρ \sqrt{ρ}} cos ( ϕ - δ ) ) cos {ϕ}^{2} \qquad ( 1 )$$

D_{psf}(ρ,φ) represents the theoretical point spread function, ρ represents a radical (transverse) coordinate of a spot, spp represents the surface plasmon polaritons, qsw represents the quasi-spherical wave, A_{SPP} represents amplitude of the surface plasmon polaritons, A_{QSW} represents amplitude of the evanescent-wave mode of the quasi-spherical wave, and ϕ−δ represents a phase delay between the surface plasmon polaritons and the quasi-spherical wave.

Step 102 is performed after the step 101.

In step 102, multiple transverse widths of spots in a spot-mapping pattern imaged from the light source onto a surface of a photoresist of the plasmon super diffraction photolithography are determined through performing atomic force microscopy on the spot-mapping pattern.

In this embodiment, the multiple transverse widths of the points in the spot-mapping pattern may be determined through the atomic force microscopy.

Step 103 is performed after the step 102.

In step 103, actual point spread functions corresponding to the multiple transverse widths are determined based on the theoretical point spread function and the multiple transverse widths.

In step 104, actual line spread functions of line patterns corresponding to different critical dimensions are determined based on multiple attenuation parameters and the actual point spread functions, which correspond to the multiple transverse widths.

In step 105, a transverse attenuation characteristic of a near-field evanescent wave of the light source is determined based on the actual line spread functions and the actual point spread functions.

In step 106, near-field photoresist contrast and a logarithmic slope of the spot-mapping pattern are determined according to the transverse attenuation characteristic.

In step 107, a variation due to line edge roughness at two boundaries of each line pattern corresponding to one of the actual line spread functions is determined based on position coordinates at the two boundaries of said line pattern.

The variation due to line edge roughness is determined by calculating a fluctuation of local position coordinates along the two boundaries.

In step 108, the near-field photoresist contrast of each line pattern is determined.

In an embodiment, a photoresist contrast induced by near-field attenuation may be determined. Then, the near-field photoresist contrast is determined based on a far-field photoresist contrast and the photoresist contrast induced by the near-field attenuation.

In step 109, an analytical equation of line edge roughness of the plasmon super diffraction photolithography is determined based on the variation due to line edge roughness, an exposure dose of each line pattern, the near-field photoresist contrast, and the logarithmic slope of each line pattern.

In the present disclosure, the analytical equation of the line edge roughness is as follows.

$$3 {σ}_{LER} ≅ \frac{3}{\sqrt{{D}_{nor}}} {e}^{\frac{1}{{r}_{near}}} ( \frac{1}{ILS} ) ,$$

σ_{LER} represents theoretical line edge roughness, Dₙₒᵣ represents the exposure dose that is normalized, rₙₑₐᵣ represents the near-field photoresist contrast, and ILS represents the logarithmic slope of the pattern.

In summary, the analytical method for quantitatively calculating line edge roughness of plasmon super diffraction photolithography is provided according to embodiments of the present disclosure. The theoretical point spread function of the light source is determined based on the field intensity distribution of the light source at the exit plane of the focusing element for the plasmon super diffraction photolithography. The multiple transverse widths of spots in the spot-mapping pattern imaged from the light source onto the surface of the photoresist of the plasmon super diffraction photolithography are determined through performing atomic force microscopy on the spot-mapping pattern. The actual point spread functions corresponding to the multiple transverse widths are determined based on the theoretical point spread function and the multiple transverse widths. The actual line spread functions of line patterns corresponding to different critical dimensions are determined based on the multiple attenuation parameters and the actual point spread functions, which correspond to the multiple transverse widths. The transverse attenuation characteristic of the near-field evanescent wave of the light source is determined based on the actual line spread functions and the actual point spread functions. The near-field photoresist contrast and the logarithmic slope of the spot-mapping pattern are determined according to the transverse attenuation characteristic. The variation due to line edge roughness at the two boundaries of each line pattern corresponding to one of the actual line spread functions is determined based on the position coordinates at the two boundaries of said line pattern. The near-field photoresist contrast of each line pattern is determined. The analytical equation of line edge roughness of the plasmon super diffraction photolithography is determined based on the variation due to line edge roughness, the exposure dose of each line pattern, the near-field photoresist contrast, and the logarithmic slope of said line pattern. The method is capable to analyze a nature of a producing mechanism of line edge roughness in the surface plasmon super diffraction photolithography, evaluate line edge roughness under different critical dimensions accurately, and provide a theoretical guidance for reducing the line edge roughness. For example, the logarithmic slope of the spot-mapping pattern may be increased by decreasing a gap of a bowtie nano-aperture, in order to reduce the line edge roughness and improve quality of the exposure pattern of surface plasmon super diffraction photolithography. In comparison with Monte Carlo simulation, the analytical method for quantitatively calculating line edge roughness of plasmon super diffraction photolithography according to embodiments the present disclosure is more suitable for a large exposure patter, and thereby applicability of the surface plasmon super diffraction photolithography is greatly improved.

FIG. 2 is a flow chart of an analytical method for quantitatively calculating line edge roughness of plasmon super diffraction photolithography according to another embodiment of the present disclosure. As shown in FIG. 2, the analytical method includes the following steps 201 to 211.

In step 201, a theoretical point spread function of a light source is determined based on field intensity distribution of a light source at an exit plane of a focusing element for the plasmon super diffraction photolithography.

In an embodiment, the field intensity distribution that finally presents on a surface of a photoresist surface via a bowtie nano-aperture (BNA) in the surface plasmon (SP) super diffraction photolithography may be modeled and analyzed. Thereby, the theoretical point spread function (PSF) is deduced, and normalization on is performed on the theoretical PSF. A critical dimension of an exposure pattern in the photoresist, as well as distribution of an exposure-field intensity in the photoresist, depend on the PSF. Therefore, an analytical equation D_{psf}(ρ,φ) of the PSF is required to be deduced.

FIG. 3 is a diagram showing field strength distribution at an exit plane of a BNA for SP super diffraction photolithography according to an embodiment of the present disclosure. As shown in FIG. 3, when exposing through an ultraviolet light source, the field strength distribution at the exit plane of the BNA is mainly determined by a near-field transverse magnetic (TM) wave and a far-field transverse electric (TE) wave. ψ₀ represents an incident electromagnetic vector field. ψ_{surf} represents a transverse propagation component of the incident electromagnetic vector field, and is mainly determined by surface plasmon polaritons (SPPs) and a evanescent-wave mode of quasi-spherical waves (QSWs). ψ_{space} represents a longitudinal propagation component of the incident electromagnetic vector field. Hence, the field intensity distribution at the exit plane of the BNA of the SP super diffraction photolithography is mainly determined by the SPPs and the evanescent-wave mode of the QSWs. When a critical dimension of the exposure pattern is approximately 1/10 of a wavelength of a light radiated by the light source, a field intensity of the SPPs decreases with a factor of 1/ρ². Accordingly, D_{psf}(ρ,φ) may be expressed by an equation (1).

$${D}_{psf} ( ρ , φ ) = ( \frac{{A}_{QSW}^{2}}{{ρ}^{2}} + \frac{{A}_{SPP}^{2}}{ρ} + \frac{{A}_{QSW} {A}_{SPP}}{ρ \sqrt{ρ}} cos ( ϕ - δ ) ) {cos}^{2} φ \qquad ( 1 )$$

A transverse length is calculated based on ρ=(xₘ²+yₘ²)^{1/2}. φ=cos⁻¹(xₘ/ρ). yₘ represents a half of a transverse width of a point in the spot-mapping pattern. xₘ represents a x-axis coordinate that corresponds to yₘ. The entire cosine term is determined by dipole radiation of local plasmon of the BNA. A_{SPP} represents amplitude of the SPPs, A_{QSW} represents amplitude of the evanescent-wave mode of the QSWs, ϕ−δ represents a phase delay between the SPPs and the QSWs. In order to eliminate an influence of photoresist sensitivity on an attenuation characteristic of the evanescent wave under different exposure doses, it is required to normalize the PSF, for example, as an equation (2).

$${PSF}_{nor} ( ρ ) = \frac{{D}_{th}}{{D}_{psf} ( ρ )} \qquad ( 2 )$$

Dₜₕ is a threshold dose, which represents minimum exposure dose to which the photoresist is sensitive.

In step 202, multiple transverse widths of spots in a spot-mapping pattern imaged from the light source onto a surface of a photoresist of the plasmon super diffraction photolithography are determined through performing atomic force microscopy (AFM) on the spot-mapping pattern.

In this embodiment, the spot-mapping pattern may be recorded on the photoresist surface through the SP super diffraction photolithography, and the multiple transverse widths of the points in the spot-mapping pattern may be determined through the atomic force microscopy.

In step 203, actual point spread functions corresponding to the multiple transverse point widths are determined based on the theoretical point spread function and the multiple transverse point widths.

FIG. 4 is a schematic diagram showing a spot-mapping pattern and PSFs corresponding to different critical dimensions according to an embodiment of the present disclosure. As shown in FIG. 4, the spot-mapping pattern may be recorded on the surface of the photoresist through the SP super diffraction photolithography, and a transverse width a point in the spot-mapping pattern may be measured through the AFM. Thereby, the PSFs (including PSF1 and PSF2) corresponding to the different widths can be obtained through measurement, and the PSFs are normalized.

In step 204, actual line spread functions of line patterns corresponding to different critical dimensions are determined based on multiple attenuation parameters and the actual point spread functions, which correspond to the multiple transverse widths.

The multiple attenuation parameters at edges of the points may be determined. The actual line spread functions corresponding to the difference critical dimensions are determined through convolution between the actual point spread functions and the line pattern. The convolution is performed by utilizing the multiple attenuation parameters based on a linear convolution relationship between the points in the spot-mapping pattern and the line patterns.

In step 205, a transverse attenuation characteristic (e.g. a function) of the near-field evanescent wave of the light source is determined based on the actual line spread functions and the actual point spread functions.

In an embodiment, attenuation parameters β corresponding to the different points may be calculated. Then, the convolution is performed between the PSFs and the line pattern corresponding to different critical dimensions, according to the linear convolution relationship between the points and the line patterns. Thereby, the line spread functions (LSF) of the line patterns corresponding to different critical dimensions can be obtained, and the LSFs are normalized. The attenuation parameter β(ρ) at an edge of a PSF may be approximated based on a linear equation β(ρ)=a+bρ, where a represents an attenuation parameter when ρ is equal to zero, and b represents a dimensionless parameter. The constants a and b are depends on spatial distribution represented by D_{psf}(ρ,φ). FIG. 5 is a schematic diagram showing a pattern of a point measured through AFM and an attenuation parameter β(ρ) at a transverse distance ρ according to an embodiment of the present disclosure. As shown in FIG. 5, β(ρ) may be acquired through data fitting based on an exposure dose at the edge of the pattern of the point.

In an embodiment, an exposure dose at the edge of the pattern of the point may be acquired. The multiple attenuation parameters are determined through data fitting based on such exposure dose, and the transverse attenuation characteristic is determined based on the attenuation parameters.

In step 206, a near-field photoresist contrast and a logarithmic slope of the spot-mapping pattern are determined according to the transverse attenuation characteristic.

In an embodiment, a correspondence between the near-field photoresist contrast and the logarithmic slope may be determined according to the transverse attenuation characteristic of the near-field evanescent wave of the light source. The logarithmic slope of the pattern is determined according to the near-field photoresist contrast and such correspondence.

In step 207, a photoresist contrast induced by near-field attenuation is determined.

In an embodiment, the spot-mapping pattern imaged from the light source onto the surface of the photoresist is acquired in an experiment of the plasmon super diffraction photolithography. Multiple transverse widths of spots in the spot-mapping pattern through atomic force microscopy. A far-field experimental photoresist contrast and a near-field experimental photoresist contrast are determined based on the multiple transverse widths and exposure doses corresponding to the multiple transverse widths. The photoresist contrast induced by the near-field attenuation is determined based on the far-field experimental photoresist contrast and the near-field experimental photoresist contrast.

In an embodiment, after analyzing the widths and the exposure dose of the points in the spot-mapping pattern, photoresist contrast curves in conventional photolithography and in the SP super diffraction photolithography are acquired. FIG. 6 is a schematic diagram showing a far-field photoresist contrast curve in a conventional photolithography system and a near-field photoresist contrast curve in a surface plasmon super diffraction photolithography system according to an embodiment of the present disclosure. As shown in FIG. 6, the photoresist contrast induced by the near-field attenuation may be determined based on the far-field experimental photoresist contrast and the near-field experimental photoresist contrast. That is, an influence of the near-field attenuation characteristic in the SP super diffraction photolithography on the photoresist contrast is analyzed.

In step 208, another near-field photoresist contrast is determined based on a far-field photoresist contrast and the photoresist contrast induced by the near-field attenuation.

The other near-field photoresist contrast is modeled and calculated on a basis of an equation of photoresist contrast,

$$( γ = {[ ln ( \frac{{D}_{c}}{{D}_{th}} ) ]}^{- 1} ) ,$$

in conventional photolithography. As a near-field photolithography technique, the SP super diffraction photolithography is different from the conventional photolithography. The photoresist contrast of the SP super diffraction photolithography is not only affected by physical and chemical properties of the photoresist and a development process, but also affected by the near-field attenuation characteristic of the SP super diffraction photolithography. Therefore, in order to accurately calculate the photoresist contrast γₙₑₐᵣ of the SP super diffraction photolithography, such photoresist contrast may be decomposed into two parts, i.e. the far-field photoresist contrast and the photoresist contrast induced by the near-field attenuation, as shown in an equation (3).

$${γ}_{near}^{- 1} = {γ}_{far}^{- 1} + {γ}_{decay}^{- 1} \qquad ( 3 )$$

That is, the other near-field photoresist contrast is determined based on the far-field photoresist contrast and the photoresist contrast induced by the near-field attenuation.

The equation for calculating such near-field photoresist contrast, i.e. γₙₑₐᵣ⁻¹=γ_{far}⁻¹+γ_{decay}⁻¹ is deduced by considering the near-field attenuation characteristic of the SP super diffraction photolithography based on the photoresist contrast equation in the conventional photolithography. Therefore, the new equation is not only applicable to the SP super diffraction photolithography, but also applicable to all nano-level photolithography techniques having near-field attenuation.

In step 209, a variation due to line edge roughness at two boundaries of a line pattern corresponding to an actual line spread functions is determined based on position coordinates at the two boundaries of the line pattern.

In this embodiment, the line pattern corresponding to the spot-mapping pattern may be acquired by a near-field probe that scans along a preset direction.

In an embodiment, the analytical equation of the line edge roughness (LER) of the SP super diffraction photolithography is derived based on a general equation for measuring the LER. FIG. 7 shows a diagram of characterizing line edge roughness in nano-level photolithography and curves of exposure dose distribution in photoresist corresponding to different critical dimensions according to an embodiment of the present disclosure. As shown in FIG. 7, when the near-field probe scans a line pattern along the x direction, the local position coordinates y₁(x) and y₂(x) at two boundaries, respectively, are obtained. τ represents a spacing between probed locations. y̅₁̅ and y̅₂̅ represent average locations of the two boundary lines, respectively. CD represents a measured critical dimension. Δy₁(xᵢ) and Δy₂(xᵢ) represent the variation of LER at the two boundaries, respectively. The above parameters may be calculated as follows.

$${\overline{y}}_{1} = \frac{{\sum }_{i = 1}^{n} {y}_{1} ( {x}_{i} )}{n} , {\overline{y}}_{2} = \frac{{\sum }_{i = 1}^{n} {y}_{2} ( {x}_{i} )}{n} , CD = \vert {\overline{y}}_{1} - {\overline{y}}_{2} \vert , \\ Δ {y}_{1} ( {x}_{i} ) = \vert {\overline{y}}_{1} - {y}_{1} ( {x}_{i} ) \vert , Δ {y}_{2} ( {x}_{i} ) = \vert {\overline{y}}_{2} - {y}_{2} ( {x}_{i} ) \vert \qquad ( 4 )$$

xᵢ represents an i-th probed location at a line edge, n=L/τ represents the number of probed locations, and L represents an exposure length of the line pattern.

In step 210, an equation for the variation due to line edge roughness is established based on the variation due to line edge roughness.

In conventional photolithography the LER is defined as three times standard deviation due to a variation at a boundary of a line pattern, as shown in an equation (5).

$$3 {σ}_{LER} = \sqrt{\frac{1}{n} {\sum }_{i = 1}^{n} {( Δ y ( {x}_{i} ) )}^{2}} \qquad ( 5 )$$

In the SP super diffraction photolithography, an exposure dose at a location yᵢ o fa boundary may be approximately expressed by using Taylor series, i.e.

$${D ( y ) = D ( {y}_{i} ) + \frac{\partial D ( y )}{\partial y} \vert}_{{y}_{i}} ( y - {y}_{i} ) + … ,$$

and the variation is Δyᵢ=(y−yᵢ). The exposure dose at the location yᵢ meets a condition of being the critical dose, that is, D(yᵢ)=Dₜₕ. The logarithmic slope corresponding to the line pattern is expressed as an equation

$${ILS = \frac{1}{D ( {y}_{i} )} \frac{\partial D ( y )}{\partial y} \vert}_{{y}_{i}} .$$

A fluctuation of the exposure dose at the boundary is expressed as n equation ΔDₑₓ=D(y)−D(yᵢ). Therefore, the variation due to line edge roughness may be approximately expressed by an equation (6).

$${{Δ {y}_{i} ≅ \frac{D ( y ) - D ( {y}_{i} )}{{D}_{th}} ( \frac{1}{{D}_{th}} \frac{\partial D ( y )}{\partial y} \vert}_{{y}_{i}} )}^{- 1} = \frac{Δ {D}_{ex}}{{D}_{th}} ( \frac{1}{ILS} ) \qquad ( 6 )$$

In step 211, an analytical equation of line edge roughness of the plasmon super diffraction photolithography is established based on the equation for the variation due to line edge roughness, the exposure dose of the line pattern, the near-field photoresist contrast, and the logarithmic slope of the line pattern.

In an embodiment, σ_{D}_{ₑₓ} represents a standard deviation of the exposure dose, and the LER may be approximately expressed by an equation (7).

$$\begin{matrix}3 {σ}_{LER} = \frac{3 {σ}_{{D}_{ex}}}{{D}_{th}} ( \frac{1}{ILS} ) = \frac{3 {σ}_{{D}_{ex}}}{{D}_{ex}} \frac{{D}_{ex}}{{D}_{th}} ( \frac{1}{ILS} ) \\ ≅ \frac{3}{\sqrt{{D}_{nor}}} {e}^{\frac{1}{{γ}_{near}}} ( \frac{1}{ILS} )\end{matrix} \qquad ( 7 )$$

Dₙₒᵣ represents the exposure dose that is normalized, and

$${γ}_{near} = {[ ln \frac{{D}_{ex}}{{D}_{th}} ]}^{- 1} .$$

In an embodiment, the analytical equation of the line edge roughness may be

$$3 {σ}_{LER} ≅ \frac{3}{\sqrt{{D}_{nor}}} {e}^{\frac{1}{{r}_{near}}} ( \frac{1}{ILS} ) .$$

σ_{LER} represents theoretical line edge roughness, Dₙₒᵣ represents the exposure dose that is normalized, rₙₑₐᵣ represents the near-field photoresist contrast, and ILS represents the logarithmic slope of the pattern. Such equation of the LER in embodiments of the present disclosure shows that a producing mechanism of the LER in the SP super diffraction photolithography process is mainly related to the exposure dose, the near-field photoresist contrast, and a random fluctuation effect in ILS. The calculation equation not only reveals an essence of how the LER is produced in the SP super diffraction photolithography, but also provides a theoretical basis for suppressing the LER. Hence, the method is of great significance for further research on SP super diffraction photolithography which has a low cost, a large applicable area, and high quality.

In an embodiment, theoretical line edge roughness of the plasmon super diffraction photolithography is determined based on the analytical equation. The line patterns corresponding to the different critical dimensions on the surface of the photoresist in the plasmon super diffraction photolithography is acquired. An image of the line patterns is processed to determine actual line edge roughness corresponding to the line patterns. Accuracy of the analytical equation is determined based on the theoretical line edge roughness and the actual line edge roughness.

The line pattern corresponding to different critical dimensions may be recorded on the surface of the photoresist through the SP super diffraction photolithography, and LER may be measured through AFM in combination with image processing. An edge (a boundary line) of the measured line pattern is extracted by using Matlab. FIG. 8 is a schematic diagram showing a line pattern and edge extraction performed on the line pattern according to an embodiment of the present disclosure. As shown in FIG. 8, the edge of the measured line pattern is extracted and the LER is calculated through Matlab. Further, the calculated theoretical LER of the line patterns under different critical dimensions is compared with the LER measured in an experiment to determine accuracy of a LER analytical model.

In embodiments of the present disclosure, the field strength distribution at the exit plane of the BNA of the focusing element for the SP super diffraction photolithography system is modeled and analyzed. It is discovered that the edge roughness of the line pattern is mainly affected by SPPs and the evanescent-wave mode of QSWs. Calculation of the attenuation parameters for the PSFs and the LSFs further shows that the transverse attenuation of near-field evanescent wave is an important optical cause of large LER in SP super diffraction photolithography system.

Analysis on the unique near-field attenuation of SP super diffraction photolithography reveals that the photoresist contrast in the SP super diffraction photolithography is different from that in the conventional photolithography, and the photoresist contrast is affected by induction of the near-field attenuation. Accordingly, the deduced equation for calculating the near-field photoresist contrast is suitable for all nano-level near-field photolithography techniques.

In embodiments of the present disclosure, the equation for calculating the LER is a simple analytical equation related to the exposure dose, the near-field photoresist contrast and the ILS. The equation is capable to analyze a nature of a producing mechanism of LER in the SP super diffraction photolithography, evaluate LER under different critical dimensions accurately, and provide a theoretical guidance for reducing the LER. For example, the ILS of the spot-mapping pattern may be increased by decreasing a gap of a bowtie nano-aperture, in order to reduce the line edge roughness and improve quality of the exposure pattern of SP super diffraction photolithography. In comparison with Monte Carlo simulation, the analytical method for quantitatively calculating LER of plasmon super diffraction photolithography according to embodiments the present disclosure is more suitable for a large exposure patter, and thereby applicability of the SP super diffraction photolithography is greatly improved.

An approximate analytical method is provided according to embodiments of the present disclosure, in order quantitatively analyze a nature of how the LER in the SP super diffraction photolithography process is produced and evaluate such LER corresponding to different critical dimensions accurately. The field intensity distribution at the exit plane of the BNA structure for the SP super diffraction photolithography is studied, and it is discovered that the PSF of the SP super diffraction photolithography is mainly determined by SPPs and the evanescent-wave mode of QSWs. The spot-mapping pattern is recorded on the surface of the photoresist for the SP super diffraction photolithography, and the PSFs may be acquired through data fitting after the transverse widths of spots in the spot-mapping pattern are measured. The LSF of the SP super diffraction photolithography may be acquired through convolution based on the exposure dose of the line pattern and the PSF. An influence of an evanescent wave on the ILS and the near-field photoresist contrast may be analyzed through data fitting based on a transverse attenuation parameter of the evanescent wave in the PSF and the LSF. On a basis of a general equation of the LER in nano-level photolithography, the theoretical approximate model for calculating the LER of the SP super diffraction photolithography may be established. The model shows that the LER in the SP super diffraction photolithography is related to the exposure dose, the ILS and the photoresist contrast. The analytical equation of the LER is a mode that can be verified by experiments, and therefore is capable to truly reflect a producing mechanism of the LER concerning each process in the SP super diffraction photolithography. The equation reveals that the LER is produced through a complex random process, and further reveals that the unique attenuation characteristic of the evanescent wave in the SP super diffraction photolithography plays a significant role in producing the LER. Further, the equation provides a theoretical basis for reducing a critical dimension error and improving uniformity of quality of the exposure pattern. Thus, the equation has good applicability in practice.

In summary, the analytical method for quantitatively calculating line edge roughness of plasmon super diffraction photolithography is provided according to embodiments of the present disclosure. The theoretical point spread function of the light source is determined based on the field intensity distribution of the light source at the exit plane of the focusing element for the plasmon super diffraction photolithography. The multiple transverse widths of spots in the spot-mapping pattern imaged from the light source onto the surface of the photoresist of the plasmon super diffraction photolithography are determined through performing atomic force microscopy on the spot-mapping pattern. The actual point spread functions corresponding to the multiple transverse widths are determined based on the theoretical point spread function and the multiple transverse widths. The actual line spread functions of line patterns corresponding to different critical dimensions are determined based on the multiple attenuation parameters and the actual point spread functions, which correspond to the multiple transverse widths. The transverse attenuation characteristic of the near-field evanescent wave of the light source is determined based on the actual line spread functions and the actual point spread functions. The near-field photoresist contrast and the logarithmic slope of the spot-mapping pattern are determined according to the transverse attenuation characteristic. The variation due to line edge roughness at the two boundaries of each line pattern corresponding to one of the actual line spread functions is determined based on the position coordinates at the two boundaries of said line pattern. The near-field photoresist contrast of each line pattern is determined. The analytical equation of line edge roughness of the plasmon super diffraction photolithography is determined based on the variation due to line edge roughness, the exposure dose of each line pattern, the near-field photoresist contrast, and the logarithmic slope of said line pattern. The method is capable to analyze a nature of a producing mechanism of line edge roughness in the surface plasmon super diffraction photolithography, evaluate line edge roughness under different critical dimensions accurately, and provide a theoretical guidance for reducing the line edge roughness. For example, the logarithmic slope of the spot-mapping pattern may be increased by decreasing a gap of a bowtie nano-aperture, in order to reduce the line edge roughness and improve quality of the exposure pattern of surface plasmon super diffraction photolithography. In comparison with Monte Carlo simulation, the analytical method for quantitatively calculating line edge roughness of plasmon super diffraction photolithography according to embodiments the present disclosure is more suitable for a large exposure patter, and thereby applicability of the surface plasmon super diffraction photolithography is greatly improved.

FIG. 9 is a schematic structural diagram of an analytical apparatus for quantitatively calculating line edge roughness of plasmon super diffraction photolithography according to an embodiment of the present disclosure. As shown in FIG. 9, the device includes a first determining module 301, a second determining module 302, a third determining module 303, a fourth determining module 304, a fifth determining module 305, a sixth determining module 306, a seventh determining module 307, an eighth determining module 308 and a ninth determining module 309.

The first determining module 301 is configured to determine a theoretical point spread function of a light source based on field intensity distribution of the light source at an exit plane of a focusing element of the plasmon super diffraction photolithography. The second determining module 302 is configured to determine multiple transverse widths of spots in a spot-mapping pattern imaged from the light source onto a surface of a photoresist of the plasmon super diffraction photolithography, through performing atomic force microscopy on the spot-mapping pattern. The third determining module 303 is configured to determine actual point spread functions corresponding to the multiple transverse widths, based on the theoretical point spread function and the multiple transverse widths. The fourth determining module 304 is configured to determine actual line spread functions of line patterns corresponding to different critical dimensions based on multiple attenuation parameters and the actual point spread functions, which correspond to the multiple transverse widths. The fifth determining module 305 is configured to determine a transverse attenuation characteristic of a near-field evanescent wave of the light source based on the actual line spread functions and the actual point spread functions. The sixth determining module 306 is configured to determine a near-field photoresist contrast and a logarithmic slope of the spot-mapping pattern according to the transverse attenuation characteristic. The seventh determining module 307 is configured to determine a variation due to line edge roughness at two boundaries of each line pattern corresponding to one of the actual line spread functions, based on position coordinates at the two boundaries of said line pattern. The eighth determining module 308 is configured to determine a near-field photoresist contrast of each line pattern. The ninth determining module 309 is configured to establish an analytical equation of line edge roughness of the plasmon super diffraction photolithography based on the variation due to line edge roughness, an exposure dose of each line pattern, the near-field photoresist contrast, and the logarithmic slope of each line pattern.

In an embodiment, the eighth determining module includes a first determining submodule and a second determining submodule. The first determining submodule is configured to determine a photoresist contrast induced by near-field attenuation. The second determining submodule is configured to determine the near-field photoresist contrast based on a far-field photoresist contrast and the photoresist contrast induced by the near-field attenuation.

In an embodiment, the first determining submodule includes a first acquiring unit, a first determining unit, a second determining unit, and a third determining unit. The first determining unit is configured to acquire the spot-mapping pattern imaged from the light source onto the surface of the photoresist in an experiment of the plasmon super diffraction photolithography. The first determining unit is configured to determine multiple transverse widths of spots in the spot-mapping pattern through atomic force microscopy. The second determining unit is configured to determine an far-field experimental photoresist contrast and a near-field experimental photoresist contrast, based on the multiple transverse widths and exposure doses corresponding to the multiple transverse widths. The third determining unit is configured to determine the photoresist contrast induced by the near-field attenuation based on the far-field experimental photoresist contrast and the near-field experimental photoresist contrast.

In an embodiment, the near-field photoresist contrast is determined based on a following equation.

$${γ}_{near}^{- 1} = {γ}_{far}^{- 1} + {γ}_{decay}^{- 1}$$

γₙₑₐᵣ represents the near-field photoresist contrast, γ_{far} represents the far-field photoresist contrast, and γ_{decay} represents the photoresist contrast induced by the near-field attenuation.

In an embodiment, the ninth determining module includes a third determining submodule and a fourth determining submodule. The third determining submodule is configured to establish an equation for the variation due to line edge roughness based on the variation due to line edge roughness. The fourth determining submodule is configured to establish the analytical equation of line edge roughness of the plasmon super diffraction photolithography based on the equation for the variation due to line edge roughness, the exposure dose of each line pattern, the near-field photoresist contrast, and the logarithmic slope of each line pattern.

In an embodiment, the field intensity distribution is determined based on surface plasmon polaritons and an evanescent-wave mode of a quasi-spherical wave. When a critical dimension of an exposure pattern is equal to 1/10 of a wavelength of a light radiated by the light source, a field intensity of the surface plasmon polaritons decreases with a factor of 1/ρ², and an analytical equation for the theoretical point spread function is as follows.

$${D}_{psf} ( ρ , φ ) = ( \frac{{A}_{qsw}^{2}}{{ρ}^{2}} + \frac{{A}_{spp}^{2}}{{ρ}^{2}} + \frac{{A}_{qsw} {A}_{spp}}{ρ \sqrt{ρ}} cos ( ϕ - δ ) ) cos {φ}^{2}$$

D_{psf}(ρ,φ) represents the theoretical point spread function, ρ represents a transverse length of a spot, spp represents the surface plasmon polaritons, qsw represents the quasi-spherical wave, A_{SPP} represents amplitude of the surface plasmon polaritons, A_{QSW} represents amplitude of the evanescent-wave mode of the quasi-spherical wave, and ϕ−δ represents a phase delay between the surface plasmon polaritons and the quasi-spherical wave.

In an embodiment, the sixth determining module includes a fifth determining submodule and a sixth determining submodule. The fifth determining submodule is configured to determine a correspondence between the near-field photoresist contrast and the logarithmic slope according to the transverse attenuation characteristic. The sixth determining submodule is configured to determine the logarithmic slope according to the near-field photoresist contrast and the correspondence.

In an embodiment, the fourth determining module includes a seventh determining submodule and an eighth determining submodule. The seventh determining submodule is configured to d determine the multiple attenuation parameters at edges of the points. The eighth determining submodule is configured to determine the actual line spread functions through convolution between the actual point spread functions and the line pattern, where the convolution is performed by utilizing the multiple attenuation parameters based on a linear convolution relationship between the points in the spot-mapping pattern and the line patterns. The seventh determining submodule includes a second acquiring unit and a fourth determining unit. The second acquiring unit is configured to acquire an exposure dose at an edge of one of the points. The fourth determining unit is configured to fit the exposure dose to determine one of the multiple attenuation parameters.

In an embodiment, the apparatus further includes a tenth determining module, an acquisition module, an eleventh determining module, and a twelfth determining module. The tenth determining module is configured to determine theoretical line edge roughness of the plasmon super diffraction photolithography based on the analytical equation. The acquisition module is configured to acquire the line patterns corresponding to the different critical dimensions on the surface of the photoresist in the plasmon super diffraction photolithography. The eleventh determining module is configured to process an image of the line patterns to determine actual line edge roughness corresponding to the line patterns. The twelfth determining module is configured to determine accuracy of the analytical equation based on the theoretical line edge roughness and the actual line edge roughness.

In an embodiment, the analytical equation of the line edge roughness is as follows.

$$3 {σ}_{LER} ≅ \frac{3}{\sqrt{{D}_{nor}}} {e}^{\frac{1}{{r}_{near}}} ( \frac{1}{ILS} )$$

σ_{LER} represents theoretical line edge roughness, Dₙₒᵣ represents the exposure dose that is normalized, rₙₑₐᵣ represents the near-field photoresist contrast, and ILS represents the logarithmic slope of the pattern.

The analytical apparatus for quantitatively calculating line edge roughness of plasmon super diffraction photolithography is provided according to embodiments of the present disclosure. The theoretical point spread function of the light source is determined based on the field intensity distribution of the light source at the exit plane of the focusing element for the plasmon super diffraction photolithography. The multiple transverse widths of spots in the spot-mapping pattern imaged from the light source onto the surface of the photoresist of the plasmon super diffraction photolithography are determined through performing atomic force microscopy on the spot-mapping pattern. The actual point spread functions corresponding to the multiple transverse widths are determined based on the theoretical point spread function and the multiple transverse widths. The actual line spread functions of line patterns corresponding to different critical dimensions are determined based on the multiple attenuation parameters and the actual point spread functions, which correspond to the multiple transverse widths. The transverse attenuation characteristic of the near-field evanescent wave of the light source is determined based on the actual line spread functions and the actual point spread functions. The near-field photoresist contrast and the logarithmic slope of the spot-mapping pattern are determined according to the transverse attenuation characteristic. The variation due to line edge roughness at the two boundaries of each line pattern corresponding to one of the actual line spread functions is determined based on the position coordinates at the two boundaries of said line pattern. The near-field photoresist contrast of each line pattern is determined. The analytical equation of line edge roughness of the plasmon super diffraction photolithography is determined based on the variation due to line edge roughness, the exposure dose of each line pattern, the near-field photoresist contrast, and the logarithmic slope of said line pattern. The apparatus is capable to analyze a nature of a producing mechanism of line edge roughness in the surface plasmon super diffraction photolithography, evaluate line edge roughness under different critical dimensions accurately, and provide a theoretical guidance for reducing the line edge roughness. For example, the logarithmic slope of the spot-mapping pattern may be increased by decreasing a gap of a bowtie nano-aperture, in order to reduce the line edge roughness and improve quality of the exposure pattern of surface plasmon super diffraction photolithography. In comparison with Monte Carlo simulation, the analytical apparatus for quantitatively calculating line edge roughness of plasmon super diffraction photolithography according to embodiments the present disclosure is more suitable for a large exposure patter, and thereby applicability of the surface plasmon super diffraction photolithography is greatly improved.

The analytical apparatus for quantitatively calculating line edge roughness of plasmon super diffraction photolithography according to embodiments of the present disclosure is capable to implement the method for quantitatively calculating line edge roughness of plasmon super diffraction photolithography concerning any one of FIGS. 1 to 8. Details are not repeated herein for conciseness.

Although the present disclosure is described herein in conjunction with embodiments, those skilled in the art can appreciate and implement alternatives of the disclosed embodiments based on teachings of the drawings, the specification, and the claims when implementing the present disclosure. In the claims, the term “comprising” does not exclude components or steps that are not listed, and the term “a/an” or “one” does not exclude a case of multiple items. A single processor or another unit may implement several functions enumerated in the claims. Means that are recorded in different dependent claims do not indicate that these means cannot be combined to achieve a good effect.

Although the present disclosure is described in conjunction with specific features and embodiments, it is apparent that various modifications and combinations can be made without departing from the spirit and scope of the present disclosure. Accordingly, the specification and the drawings are merely exemplary description of the present disclosure that is defined in the claims, and should be construed to cover all modifications, changes, combinations or equivalents within the scope of the present disclosure. Apparently, those skilled in the art may make various changes and variations to the present disclosure without departing from the spirit and scope of the present disclosure. Hence, such changes and variations of the present disclosure fall within the scope of the claims of the present disclosure and equivalent technologies thereof, and the present disclosure is intended for including such changes and variations.

1. An analytical method for quantitatively calculating line edge roughness of plasmon super diffraction photolithography, comprising:
determining a theoretical point spread function of a light source based on field intensity distribution of the light source at an exit plane of a focusing element of the plasmon super diffraction photolithography;
determining a plurality of transverse widths of spots in a spot-mapping pattern imaged from the light source onto a surface of a photoresist of the plasmon super diffraction photolithography, through performing atomic force microscopy on the spot-mapping pattern;
determining actual point spread functions corresponding to the plurality of transverse widths, based on the theoretical point spread function and the plurality of transverse widths;
determining actual line spread functions of line patterns corresponding to different critical dimensions based on a plurality of attenuation parameters and the actual point spread functions, which correspond to the plurality of transverse widths;
determining a transverse attenuation characteristic of a near-field evanescent wave of the light source based on the actual line spread functions and the actual point spread functions;
determining a near-field photoresist contrast and a logarithmic slope of the spot-mapping pattern according to the transverse attenuation characteristic;
determining a variation due to line edge roughness at two boundaries of each line pattern corresponding to one of the actual line spread functions, based on position coordinates at the two boundaries of said line pattern;
determining the near-field photoresist contrast of each line pattern;
establishing an analytical equation of line edge roughness of the plasmon super diffraction photolithography based on the variation due to line edge roughness, an exposure dose of each line pattern, the near-field photoresist contrast, and the logarithmic slope of each line pattern; and
calculating the line edge roughness based on the analytical equation.

2. The method according to claim 1, wherein determining the near-field photoresist contrast of each line pattern comprises:
determining a photoresist contrast induced by near-field attenuation; and
determining the near-field photoresist contrast of each line pattern based on a far-field photoresist contrast and the photoresist contrast induced by the near-field attenuation.

3. The method according to claim 2, wherein determining the photoresist contrast induced by the near-field attenuation comprises:
acquiring the spot-mapping pattern imaged from the light source onto the surface of the photoresist in an experiment of the plasmon super diffraction photolithography;
determining a plurality of transverse widths of spots in the spot-mapping pattern through atomic force microscopy;
determining a far-field experimental photoresist contrast and a near-field experimental photoresist contrast, based on the plurality of transverse widths of spots in the spot-mapping pattern and exposure doses corresponding to the plurality of transverse widths of spots in the spot-mapping pattern; and
determining the photoresist contrast induced by the near-field attenuation based on the far-field experimental photoresist contrast and the near-field experimental photoresist contrast.

4. The method according to claim 2, wherein the near-field photoresist contrast is determined based on:
$${γ}_{near}^{- 1} = {γ}_{far}^{- 1} + {γ}_{decay}^{- 1} ,$$
wherein γₙₑₐᵣ represents the near-field photoresist contrast, γ_{far} represents the far-field photoresist contrast, and γ_{decay} represents the photoresist contrast induced by the near-field attenuation.

5. The method according to claim 1, wherein establishing the analytical equation of line edge roughness of the plasmon super diffraction photolithography based on the variation due to line edge roughness, the exposure dose of each line pattern, the near-field photoresist contrast, and the logarithmic slope of each line pattern comprises:
establishing an equation for the variation due to line edge roughness based on the variation due to line edge roughness and the logarithmic slope of each line pattern; and
establishing the analytical equation of line edge roughness of the plasmon super diffraction photolithography based on the equation for the variation due to line edge roughness, the exposure dose of each line pattern, the near-field photoresist contrast.

6. The method according to claim 1, wherein:
the field intensity distribution is determined based on surface plasmon polaritons and an evanescent-wave mode of a quasi-spherical wave;
when a critical dimension of an exposure pattern is equal to 1/10 of a wavelength of a light radiated by the light source, a field intensity of the surface plasmon polaritons decreases with a factor of 1/ρ², and
an analytical equation for the theoretical point spread function is:
$${D}_{psf} ( ρ , φ ) = ( \frac{{A}_{qsw}^{2}}{{ρ}^{2}} + \frac{{A}_{spp}^{2}}{{ρ}^{2}} + \frac{{A}_{qsw} {A}_{spp}}{ρ \sqrt{ρ}} cos ( ϕ - δ ) ) cos {φ}^{2} ,$$
wherein D_{psf}(ρ,φ) represents the theoretical point spread function, ρ represents a transverse length of a spot, spp represents the surface plasmon polaritons, qsw represents the quasi-spherical wave, A_{SPP} represents amplitude of the surface plasmon polaritons, A_{QSW} represents amplitude of the evanescent-wave mode of the quasi-spherical wave, and ϕ−δ represents a phase delay between the surface plasmon polaritons and the quasi-spherical wave.

7. The method according to claim 1, wherein determining the near-field photoresist contrast and the logarithmic slope of the spot-mapping pattern according to the transverse attenuation characteristic comprises:
determining a correspondence between the near-field photoresist contrast and the logarithmic slope according to the transverse attenuation characteristic; and
determining the logarithmic slope according to the near-field photoresist contrast and the correspondence.

8. The method according to claim 1, wherein:
determining the actual line spread functions of the line patterns corresponding to the different critical dimensions based on the plurality of attenuation parameters and the actual point spread functions, which correspond to the plurality of transverse widths, comprises:
determining the plurality of attenuation parameters at edges of the points; and
determining the actual line spread functions through convolution between the actual point spread functions and the line pattern, wherein the convolution is performed by utilizing the plurality of attenuation parameters based on a linear convolution relationship between the points in the spot-mapping pattern and the line patterns; and
determining the plurality of attenuation parameters at edges of the points comprises:
acquiring an exposure dose at an edge of one of the points; and
fitting the exposure dose to determine an attenuation parameter of the plurality of attenuation parameters.

9. The method according to claim 1, wherein after establishing the analytical equation of the line edge roughness of the plasmon super diffraction photolithography based on the variation due to line edge roughness, the exposure dose of each line pattern, the near-field photoresist contrast, and the logarithmic slope of each line pattern, the method further comprises:
determining theoretical line edge roughness of the plasmon super diffraction photolithography based on the analytical equation;
acquiring the line patterns corresponding to the different critical dimensions on the surface of the photoresist in the plasmon super diffraction photolithography;
processing an image of the line patterns to determine actual line edge roughness corresponding to the line patterns; and
determining accuracy of the analytical equation based on the theoretical line edge roughness and the actual line edge roughness.

10. The method according to claim 1, wherein the analytical equation of the line edge roughness is:
$$3 {σ}_{LER} ≅ \frac{3}{\sqrt{{D}_{nor}}} {e}^{\frac{1}{{r}_{near}}} ( \frac{1}{ILS} ) ,$$
wherein 3 σ_{LER} represents theoretical line edge roughness, Dₙₒᵣ represents the exposure dose that is normalized, rₙₑₐᵣ represents the near-field photoresist contrast, and ILS represents the logarithmic slope of the pattern.

11. An analytical apparatus for quantitatively calculating line edge roughness of plasmon super diffraction photolithography, comprising:
a first determining module, configure to determine a theoretical point spread function of a light source based on field intensity distribution of the light source at an exit plane of a focusing element of the plasmon super diffraction photolithography;
a second determining module, configured to determine a plurality of transverse widths of spots in a spot-mapping pattern imaged from the light source onto a surface of a photoresist of the plasmon super diffraction photolithography, through performing atomic force microscopy on the spot-mapping pattern;
a third determining module, configured to determine actual point spread functions corresponding to the plurality of transverse widths, based on the theoretical point spread function and the plurality of transverse widths;
a fourth determining module, configured to determine actual line spread functions of line patterns corresponding to different critical dimensions based on a plurality of attenuation parameters and the actual point spread functions, which correspond to the plurality of transverse widths;
a fifth determining module, configured to determine a transverse attenuation characteristic of a near-field evanescent wave of the light source based on the actual line spread functions and the actual point spread functions;
a sixth determining module, configured to determine a near-field photoresist contrast and a logarithmic slope of the spot-mapping pattern according to the transverse attenuation characteristic;
a seventh determining module, configured to determine a variation due to line edge roughness at two boundaries of each line pattern corresponding to one of the actual line spread functions, based on position coordinates at the two boundaries of said line pattern;
an eighth determining module, configured to determine a near-field photoresist contrast of each line pattern; and
a ninth determining module, configured to establish an analytical equation of line edge roughness of the plasmon super diffraction photolithography based on the variation due to line edge roughness, an exposure dose of each line pattern, the near-field photoresist contrast, and the logarithmic slope of each line pattern.
